(19) United States
(12) Patent Application Publication
(10) Pub. No.: US 2026/0354274 A1
(43) Pub. Date: Nov. 5, 2026

(54) PACKAGE-ON-PACKAGE STRUCTURE INCLUDING A THERMAL ISOLATION MATERIAL

(71) Applicant: Taiwan Semiconductor Manufacturing Co., Ltd., Hsinchu (TW)

(72) Inventors: Meng-Tse Chen, Changzhi Township (TW); Kuei-Wei Huang, Hsinchu (TW); Tsai-Tsung Tsai, Taoyuan City (TW); Ai-Tee Ang, Hsinchu (TW); Ming-Da Cheng, Taoyuan City (TW); Chung-Shi Liu, Hsinchu (TW)

(21) Appl. No.: 19/734,402

(22) Filed: Jul. 8, 2026

Related U.S. Application Data
(63) Continuation of application No. 18/361,515, filed on Jul. 28, 2023.
Application No. 18/361,515 is a continuation of application No. 16/580,617, filed on Sep. 24, 2019, now Pat. No. 11,776,945.
Application No. 16/580,617 is a continuation of application No. 15/228,098, filed on Aug. 4, 2016, now Pat. No. 10,490,539.
Application No. 15/228,098 is a continuation of application No. 13/671,665, filed on Nov. 8, 2012, now Pat. No. 9,418,971.

(51) Int. Cl. H10W 90/00; H10W 40/70; H10W 70/60; H10W 74/01; H10W 74/10; H10W 76/60; H10W 72/00; H10W 90/20

(52) U.S. Cl. CPC H10W 90/00; H10W 40/70; H10W 70/611; H10W 74/01; H10W 74/117; H10W 76/60; H10W 90/401; H10W 90/701; H10W 70/60; H10W 72/877; H10W 72/884; H10W 90/288; H10W 90/722; H10W 90/724; H10W 90/732; H10W 90/734; H10W 90/754

(57) ABSTRACT

A semiconductor device includes a first package component and a second package component. The first package component has a first die formed on a first substrate. A second package component has a second die formed on a second substrate. A thermal isolation material is attached on the first die, wherein the thermal isolation material thermally insulates the second die from the first die, and the thermal isolation material has a thermal conductivity of from about 0.024 W/mK to about 0.2 W/mK. A first set of conductive elements couples the first package component to the second package component.

### PRIORITY CLAIM AND CROSS-REFERENCE

This application is a continuation of U.S. Patent Application No. 18/361,515, entitled “Package-on-Package Structure Including a Thermal Isolation Material,” filed on Jul. 28, 2023, which is a continuation of U.S. Patent Application No. 16/580,617, entitled “Package-on-Package Structure Including a Thermal Isolation Material,” filed on Sep. 24, 2019, now U.S. Patent No. 11,776,945, issued Oct. 3, 2023, which is a continuation of U.S. Patent Application No. 15/228,098, entitled, “Package-on-Package Structure Including a Thermal Isolation Material and Method of Forming the Same,” filed on Aug. 4, 2016, now U.S. Patent No. 10,490,539 issued Nov. 26, 2019, which is a continuation of U.S. Patent Application No. 13/671,665, entitled “Package-on-Package Structure Including a Thermal Isolation Material and Method of Forming the Same,” filed on Nov. 8, 2012, now U.S. Patent No. 9,418,971 issued Aug. 16, 2016, which applications are incorporated herein by reference.

### BACKGROUND

Package-on-package (POP) is becoming an increasingly popular integrated circuit packaging technique because it allows for higher density electronics.

A conventional package-on-package structure may include a bottom package component and a top package component. The bottom package component may include a bottom die attached to a bottom substrate and the top package component may include a top die attached to a top substrate. The bottom package component is coupled to the top package component typically by a set of conductive elements, such as solder balls. In operation, both package components generate heat. However, excessive heat that is generated by the bottom die, especially where the bottom die is a device die, may cause damage to the top die. The heat can also cause thermal stress and warpage in the package-on-package structure leading to cracks in the solder balls. Even with the use of molding compounds in the package-on-package structure, the problem of excess heat and warpage still cannot be entirely eliminated.

### BRIEF DESCRIPTION OF THE DRAWINGS

Embodiments of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart of a method of fabricating a package-on-package structure according to various embodiments of the present disclosure.

FIGS. 2-6 are cross-sectional views of a top package and/or a bottom package at various intermediate stages in the manufacture of a package-on-package structure, in accordance with various embodiments of the present disclosure.

### DETAILED DESCRIPTION

In the following description, specific details are set forth to provide a thorough understanding of embodiments of the present disclosure. However, one having an ordinary skill in the art will recognize that embodiments of the disclosure can be practiced without these specific details. In some instances, well-known structures and processes are not described in detail to avoid unnecessarily obscuring embodiments of the present disclosure.

Reference throughout this specification to "one embodiment" or "an embodiment" means that a particular feature, structure, or characteristic described in connection with the embodiment is included in at least one embodiment of the present disclosure. Thus, the appearances of the phrases "in one embodiment" or "in an embodiment" in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are intended for illustration.

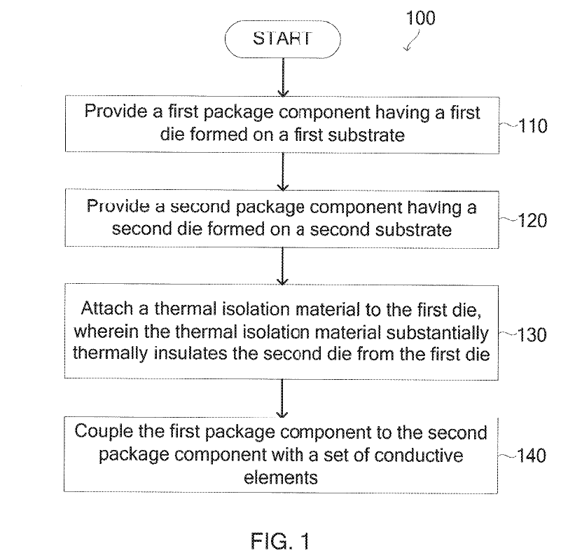

FIG. 1 is a flowchart of a method 100 for fabricating a package-on-package according to various aspects of the present disclosure. Referring to FIG. 1, the method includes block 110, in which a first package component is provided, the first package component having a first die formed on a first substrate. The method 100 includes block 120, in which a second package component is provided, the second package component having a second die formed on a second substrate. The method 100 includes block 130, in which a thermal isolation material is attached to the first die. The thermal isolation material substantially thermally insulates the second die from the first die. The method 100 includes block 140, in which the first package component is coupled to the second package component with a set of conductive elements.

It is understood that additional processes may be performed before, during, or after the blocks 110-140 shown in FIG. 1 to complete the fabrication of the package-on-package structure, but these additional processes are not discussed herein in detail for the sake of simplicity.

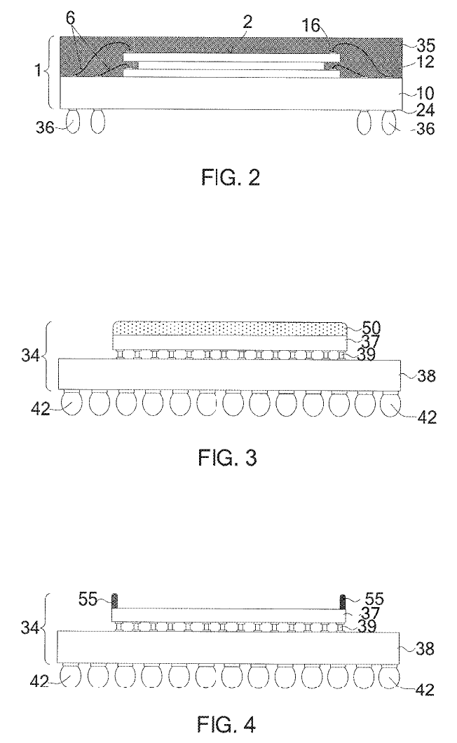

FIGS. 2-6 are diagrammatic fragmentary cross-sectional side views of a top package and/or a bottom package at various fabrication stages of manufacturing a package-on-package structure according to embodiments of the method 100 of FIG. 1. It is understood that FIGS. 2-6 have been simplified for a better understanding of the inventive concepts of the present disclosure. It should be appreciated that the materials, geometries, dimensions, structures, and process parameters described herein are exemplary only, and are not intended to be, and should not be construed to be, limiting to the invention claimed herein. Many alternatives and modifications will be apparent to those skilled in the art, once informed by the present disclosure.

An embodiment package-on-package structure will be discussed with reference to FIGS. 2-6. FIG. 2 illustrates a top package 1 to be employed in the package-on-package structure. Top package 1, which may be formed using a plastic ball grid array (PBGA) package assembly process or the like, includes a plurality of stacked die 2, which may be wired bonded to top substrate 10 by way of contacts 16 (on respective stacked die 2), bond wires 6, and contacts 12 (on top substrate 10). Individual stacked die may comprise a memory chip, a logic chip, a processor chip, or the like. Although FIG. 2 illustrates three stacked die, this is for illustration only. Likewise, the use of wire bonding is merely illustrative, and other approaches for electrically connecting the stacked die are within the contemplated scope of the present disclosure. For example, solder bumps, solder balls, copper pillars, conductive bumps, solder caps, conductive pillars, conductive balls, under-bump metallurgies, and/or other connector elements may also be contemplated to connect stacked die 2 to top substrate 10. In some embodiments, an underfill (not shown) is dispensed into the gap between stacked die 2 and top substrate 10 to reinforce the strength of the package-on-package structure.

Top substrate 10 may be a laminated circuit board comprised of alternating layers of non-conductive polymers, such as bismaleinide-triazine (BT), and patterned (or non-patterned) conductive layers. As discussed above, top substrate 10 has contacts 12 on a first side (referred to herein sometimes as a top side for convenience) for electrical connection to stacked die 2. Top substrate 10 further has bottom contacts 24 on a second side (sometimes referred to as a bottom side) for electrical connection to other components as will be detailed further below. Solder balls 36 are attached to bottom contacts 24 to top substrate 10. Solder balls 36 allow for electrical and/or thermal connection between top package 1 and a bottom package 34 (not shown in FIG. 2, but illustrated in FIGS. 3 and 4). In the illustrated embodiment, solder balls 36 provide for electrical conduction of signals and power to stacked die 2. Again, other connection components, such as conductive bumps, conductive balls, conductive pillars, and the like, could be employed in lieu of solder balls 36.

In some embodiments, a molding compound 35 is applied to top package 1 to provide mechanical stiffness and enhance the mechanical strength of the package-on-package structure. It is believed that this mechanical stiffness prevents, or at least reduces, the severity of warpages resulting from, for example, thermal expansion mismatch between the components of the resulting package. Molding compound 35 may be molded on substrate 10 and surrounds stacked die 2 and bond wires 6 using, for example, compressive molding or transfer molding. A curing step may then be performed to solidify the molding compound 35. The molding compound 35 may comprise a polymer-based material, an underfill, a molding underfill (MUF), an epoxy, or the like.

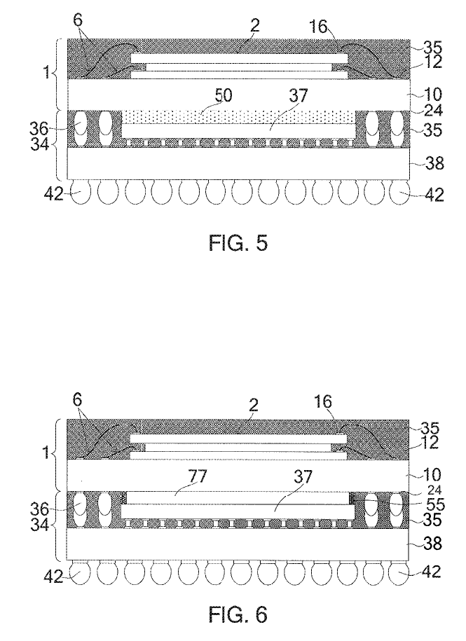

Top package 1 is attached to a bottom package 34, as illustrated in FIG. 5 by way of solder balls 36. As depicted in FIG. 3, the bottom package 34 includes die 37, which is flip chip attached to a bottom substrate 38, and which is electrically connected thereto by way of connector elements 39. Die 37 may comprise a logic chip, a processor chip, a memory chip, or the like. Connector elements 39 may include, for example solder bumps, solder balls, copper pillars, conductive bumps, solder caps, conductive pillars, conductive balls, and under-bump metallurgies. In some embodiments, an underfill (not shown) is dispensed into the gap between die 37 and bottom substrate 38 to reinforce the strength of the package-on-package structure. Electrical connection between die 37 and an underlying mother board or other circuitry (not shown) is provided by through vias (not shown) aligned with connector elements 39 on one side of bottom substrate 38 and connector elements 42 on the other side of bottom substrate 38. Likewise, electrical connection between top substrate 10 and an underlying mother board or other circuitry is provided by solder balls 36, through vias, and connector elements 42.

In operation, both the bottom package 34 and the top package 1 that include die 37 and stacked die 2, respectively generate heat. Heat that is generated by die 37, especially where the bottom die is a processor die, may cause damage to the top die or stacked die 2. The heat can also cause thermal stress and warpage in the package-on-package structure leading to cracks in the connector elements, such as solder balls. An advantageous feature of the package-on-package structure of the present disclosure is a thermal isolation material 50 of the bottom package 34, as depicted in FIG. 3, attached above die 37 and thermally insulates stacked die 2 from the heat generated by die 37. In one embodiment, as an additional benefit because the top package 1 and bottom package 34 are insulated from heat thanks to the thermal isolation material 55, warpage in the package-on-package structure is better controlled. In other words, thermal isolation material 55 provides resistance to warping that might otherwise occur as a result of thermal coefficient of expansion (CTE) mismatch between top package 1 and bottom packager 34.

In some embodiments, the thermal isolation material 50 is a material having a thermal conductivity of from about 0.024 W/mK to about 0.2 W/mK. The thermal isolation material 50 may comprise a porous film, a wax film, a die attach film (DAF), an aerogel, a tape, a thermal interface material (TIM), or an adhesive. Where the thermal isolation material 50 is a TIM, the TIM may comprise a solder paste, an adhesive, or thermal grease. In some embodiments, the thermal isolation material 50 has a thickness ranging from about 10 microns to about 100 microns.

FIG. 5 shows the thermal isolation material 50 in the package-on-package structure where the bottom package 34 is attached to the top package 1.

In other embodiments, the thermal isolation material 50 is a seal ring 55 having air or vacuum 77 therein, as shown in FIG. 4 and as shown in FIG. 6. The seal ring 55 is formed in the package-on-package structure where the bottom package 34 is attached to top package 1. Air or vacuum is an ideal thermal insulator under normal operation conditions. In other embodiments, the seal ring 55 provides a thermal conductivity of about 0 W/mK. Seal ring 55 is dispensed on die 37 to provide a vacuum gap during a molding process that will be explained below.

After either the thermal isolation material 50 or the seal ring 55 has been applied to die 37, in some embodiments, a molding compound 35 is applied to bottom package 34 to provide mechanical stiffness and enhance the mechanical strength of the package-on-package structure. Molding compound 35 may be molded on substrate 38 and surround die 37 and connector elements 39 using, for example, compressive molding or transfer molding. A curing step may then be performed to solidify the molding compound 35. The molding compound 35 may comprise a polymer-based material, an underfill, a molding underfill (MUF), an epoxy, or the like. Referring back to FIG. 4, to form the air or vacuum 77, the molding compound 35 is formed around the seal ring 55, thereby encapsulating the air or vacuum 77 therein.

The package-on-package structures shown in FIGS. 2-6 are only for illustrative purpose and are not limiting. Additional embodiments can be conceived.

Advantages of one or more embodiments of the present disclosure may include one or more of the following.

In one or more embodiments, in a package-on-package structure having a top package with a top die and a bottom package with a bottom die, the top die is substantially insulated from the heat generated by the bottom die.

In one or more embodiments, warpage in a package-on-package structure is better to control because the top package and the bottom package are substantially insulated from heat.

The present disclosure has described various exemplary embodiments. According to one embodiment, a semiconductor device includes a first package component and a second package component. The first package component has a first die formed on a first substrate. The second package component has a second die formed on a second substrate. A first set of conductive elements couples the first package component to the second package component. A thermal isolation material is applied on the first die and interjacent the first package component and the second package component, wherein the thermal isolation material thermally insulates the second die from the first die. In some embodiments, the thermal isolation material includes a seal ring and an air gap.

According to another embodiment, a package-on-package includes a bottom package component and a top package component. The bottom package component has at least a bottom die formed on a bottom substrate. The top package component has at least a top die formed on a top substrate. A thermal isolation material is attached to the bottom die, wherein the thermal isolation material thermally insulates the top die from the bottom die. The thermal isolation material has a thermal conductivity of from about 0.024 W/mK to about 0.2 W/mK. A first set of conductive elements couples the bottom substrate to the top substrate. In some embodiments, the thermal isolation material includes a seal ring and an air gap.

According to yet another embodiment, a method of forming a package is disclosed. A first package component is provided, and the first package component has a first die formed on a first substrate. A second package component is provided, and the second package component has a second die formed on a second substrate. A thermal isolation material is attached to the first die, wherein the thermal isolation material thermally insulates the second die from the first die. The first package component is coupled to the second package component with a first set of conductive elements. In some embodiments, the thermal isolation material includes a seal ring and an air gap.

In the preceding detailed description, specific exemplary embodiments have been described. It will, however, be apparent to a person of ordinary skill in the art that various modifications, structures, processes, and changes may be made thereto without departing from the broader spirit and scope of the present disclosure. The specification and drawings are, accordingly, to be regarded as illustrative and not restrictive. It is understood that embodiments of the present disclosure are capable of using various other combinations and environments and are capable of changes or modifications within the scope of the claims.

What is claimed is:

1. A structure comprising:
a bottom substrate;
a first device die over and bonded to the bottom substrate through electrical connector elements;
a ring feature formed of a thermal insulating material, wherein the ring feature is a full ring without break, and the ring feature encircles an inner region therein;
a top package over the bottom substrate and the ring feature, wherein the top package comprises a top substrate, and a second device die over the top substrate;
solder regions electrically connecting the top package to the bottom substrate; and
an encapsulant encapsulating the first device die and the ring feature therein, wherein the encapsulant extends from a bottom surface of the ring feature to a top surface of the ring feature.

2. The structure of claim 1, wherein the inner region comprises an air gap.

3. The structure of claim 1, wherein the inner region is vacuum sealed.

4. The structure of claim 1, wherein edges of the ring feature are flush with respective edges of the first device die.

5. The structure of claim 1, wherein the inner region overlaps a majority of the first device die.

6. The structure of claim 1, wherein a top surface of the first device die is exposed to the inner region.

7. The structure of claim 1, wherein the encapsulant comprises a top surface contacting the top package, and a bottom surface contacting the bottom substrate.

8. The structure of claim 1, wherein the ring feature comprises a dielectric material.

9. The structure of claim 1, wherein in a cross-sectional view of the structure, a portion of the ring feature adjacent to a respective edge of the first device die is elongated, and wherein in the cross-sectional view, a lengthwise direction of the portion is in a direction perpendicular to a top surface of the device die.

10. The structure of claim 1, wherein the top surface of the ring feature is coplanar with an additional top surface of the encapsulant.

11. A structure comprising:
a first package component comprising:
a first package substrate; and
a first device die over and bonded to the first package substrate;
a second package component comprising:
a second package substrate; and
a second device die over and bonded to the second package substrate;
a plurality of solder regions electrically connecting the first package substrate to the second package substrate;
a thermal isolation region contacting the first device die, the first package substrate, and the second package substrate, wherein the thermal isolation region comprises:
a thermal insulation material forming a ring; and
an air gap or a vacuumed region encircled by the ring; and
a molding compound forming a straight interface with the thermal insulation material and the first device die, wherein the thermal isolation region has a first thermal conductivity lower than a second thermal conductivity of the molding compound.

12. The structure of claim 11, wherein the straight interface comprises:
a first portion formed between the molding compound and the thermal isolation region; and
a second portion formed between the molding compound and the first device die, wherein in a cross-sectional view of the structure, the first portion and the second portion are aligned to a same straight line.

13. The structure of claim 11, wherein the molding compound is in physical contact with the first package substrate and the second package substrate.

14. The structure of claim 11, wherein the thermal insulation material comprises outer edges contacting the molding compound, and inner edges parallel to the outer edges.

15. The structure of claim 11, wherein the air gap or the vacuumed region overlaps a majority of the first device die.

16. The structure of claim 11, wherein the thermal isolation region and the molding compound comprise different materials, and wherein the thermal isolation region and the molding compound form vertical interfaces.

17. A structure comprising:
a bottom package component comprising:
a bottom substrate; and
a bottom die over and electrically coupled to the bottom substrate, wherein a first edge of the bottom die is laterally recessed from a second edge of the bottom substrate;
a top package component over and bonded to the bottom package component;
a thermal isolation material over and attached to the bottom die, wherein the thermal isolation material comprises a seal ring having air or vacuum therein; and
a molding compound encircling the thermal isolation material, wherein the molding compound contacts outer sidewalls of the seal ring to form vertical interfaces, and wherein the molding compound comprises a portion laterally between the first edge and the second edge, with the portion being in contact with the bottom substrate and the top package component.

18. The structure of claim 17, wherein the molding compound comprises a material different from the thermal isolation material.

19. The structure of claim 17, wherein in a cross-sectional view of the structure, the molding compound is outside of a region directly over the bottom die.

20. The structure of claim 17, wherein the seal ring comprises an outer edge and an inner edge opposing to each other, and wherein the outer edge and the inner edge are straight edges that are parallel to each other.
